(19) United States
(12) Patent Application Publication
(10) Pub. No.: US 2024/0347603 A1
(43) Pub. Date: Oct. 17, 2024

(54) NITRIDE SEMICONDUCTOR DEVICE AND METHOD FOR MANUFACTURING THE SAME

(71) Applicant: ROHM CO., LTD., Kyoto-shi (JP)

(72) Inventors: Norikazu ITO, Kyoto-shi (JP); Keita SHIKATA, Kyoto-shi (JP); Taketoshi TANAKA, Kyoto-shi (JP)

(73) Assignee: ROHM CO., LTD., Kyoto-shi (JP)

(21) Appl. No.: 18/751,377

(22) Filed: Jun. 24, 2024

Related U.S. Application Data
(63) Continuation of application No. PCT/JP2022/046180, filed on Dec. 15, 2022.

(30) Foreign Application Priority Data
Dec. 27, 2021 (JP) 2021-212275

(51) Int. Cl. H01L 29/20; H01L 21/02; H01L 29/10; H01L 29/66; H01L 29/786

(52) U.S. Cl. CPC H01L 29/2003; H01L 21/0228; H01L 21/0254; H01L 29/1066; H01L 29/66462; H01L 29/78618

(57) ABSTRACT

A nitride semiconductor device includes a low resistance Si substrate that has a first principal surface and a second principal surface opposite thereto, a high resistance Si layer that is formed on the first principal surface and is higher in resistivity than the low resistance Si substrate, and a nitride epitaxial layer that is disposed on the high resistance Si layer.

### CROSS-REFERENCE TO RELATED APPLICATIONS

The present application is a continuation application of PCT Application No. PCT/JP2022/046180, filed on Dec. 15, 2022, which corresponds to Japanese Patent Application No. 2021-212275 filed on Dec. 27, 2021, with the Japan Patent Office, and the entire disclosure of these applications is incorporated herein by reference.

### TECHNICAL FIELD

The present disclosure relates to a nitride semiconductor device that is constituted of a group III nitride semiconductor (hereinafter referred to at times simply as “nitride semiconductor”) and a method for manufacturing the same.

### BACKGROUND ART

A group III nitride semiconductor is a semiconductor among group III-V semiconductors with which nitrogen is used as the group V element. Aluminum nitride (AlN), gallium nitride (GaN), and indium nitride (InN) are representative examples. It can generally be expressed as AlₓIn_{y}Ga_{1-x-y}N (0≤x≤1, 0≤y≤1, 0≤x+y≤1).

Generally, in a nitride semiconductor device used in a high frequency application, an SiC substrate that is semi-insulating is used as a semiconductor substrate to reduce a parasitic capacitance (see, for example, Japanese Patent Application Publication No. 2019-110256).

### BRIEF DESCRIPTION OF DRAWINGS

FIG. 1 is a sectional view for describing the arrangement of a nitride semiconductor device according to a first preferred embodiment of the present disclosure.

FIG. 2A is a sectional view showing an example of a manufacturing process of the nitride semiconductor device.

FIG. 2B is a sectional view showing a step subsequent to that of FIG. 2A.

FIG. 2C is a sectional view showing a step subsequent to that of FIG. 2B.

FIG. 2D is a sectional view showing a step subsequent to that of FIG. 2C.

FIG. 2E is a sectional view showing a step subsequent to that of FIG. 2D.

FIG. 2F is a sectional view showing a step subsequent to that of FIG. 2E.

FIG. 3 is a sectional view for describing the arrangement of a nitride semiconductor device according to a second preferred embodiment of the present disclosure.

FIG. 4 is a sectional view showing a modification example of a source electrode of the nitride semiconductor device of FIG. 1.

FIG. 5 is a sectional view showing a modification example of the source electrode of the nitride semiconductor device of FIG. 3.

### DESCRIPTION OF EMBODIMENTS

A preferred embodiment of the present disclosure provides a nitride semiconductor device including a low resistance Si substrate that has a first principal surface and a second principal surface opposite thereto, a high resistance Si layer that is formed on the first principal surface and is higher in resistivity than the low resistance Si substrate, and a nitride epitaxial layer that is disposed on the high resistance Si layer.

With this arrangement, the nitride semiconductor device that uses the low resistance Si substrate as a semiconductor substrate and is a nitride semiconductor device that enables suppression of warping of the low resistance Si substrate and internal cracking of the nitride epitaxial layer and reduction of parasitic capacitance can be obtained.

In the preferred embodiment of the present disclosure, the first principal surface is a (111) plane.

In the preferred embodiment of the present disclosure, a resistivity of the low resistance Si substrate is not more than 0.01 Ω·cm and a resistivity of the high resistance Si layer is not less than 1 Ω·cm.

In the preferred embodiment of the present disclosure, an acceptor type impurity is contained in each of the low resistance Si substrate and the high resistance Si layer, an acceptor type impurity concentration of the low resistance Si substrate is not less than 1×10¹⁸ cm⁻³ and not more than 1×10²¹ cm⁻³, and an acceptor type impurity concentration of the high resistance Si layer is not less than 1×10¹³ cm⁻³ and not more than 1×10¹⁶ cm⁻³.

In the preferred embodiment of the present disclosure, the acceptor type impurity is boron.

In the preferred embodiment of the present disclosure, the nitride epitaxial layer includes a buffer layer that is formed on the high resistance Si layer and is constituted of a nitride semiconductor, a first nitride semiconductor layer that is disposed on the buffer layer and constitutes an electron transit layer, and a second nitride semiconductor layer that is formed on the first nitride semiconductor layer, constitutes an electron supply layer, and is higher in bandgap than the first nitride semiconductor layer.

In the preferred embodiment of the present disclosure, the buffer layer includes an AlN layer that is formed on the high resistance Si layer and an AlGaN layer that is formed on the AlN layer, the first nitride semiconductor layer includes an undoped GaN layer that is disposed on the buffer layer, and the second nitride semiconductor layer includes an AlGaN layer.

In the preferred embodiment of the present disclosure, a semi-insulating nitride layer that is disposed between the buffer layer and the first nitride semiconductor layer is included.

In the preferred embodiment of the present disclosure, the buffer layer includes an AlN layer that is formed on the high resistance Si layer and an AlGaN layer that is formed on the AlN layer, the semi-insulating nitride layer includes a semi-insulating GaN layer that is disposed on the buffer layer and is doped with an impurity, the first nitride semiconductor layer includes an undoped GaN layer that is formed on the semi-insulating nitride layer, and the second nitride semiconductor layer includes an AlGaN layer.

In the preferred embodiment of the present disclosure, the impurity is carbon.

In the preferred embodiment of the present disclosure, a source electrode, a drain electrode, and a gate electrode that are disposed on the nitride epitaxial layer are included, a hole reaching the low resistance Si substrate from a front surface of the nitride epitaxial layer is formed, and the source electrode is electrically connected to the low resistance Si substrate via the hole.

In the preferred embodiment of the present disclosure, a nitride semiconductor gate layer that is formed between the gate electrode and the nitride epitaxial layer and is constituted of a nitride semiconductor layer containing an acceptor type impurity is included.

In the preferred embodiment of the present disclosure, a rear surface electrode that is formed on the second principal surface is included.

A preferred embodiment of the present disclosure provides a method for manufacturing a nitride semiconductor device including a step of forming, on a first principal surface of a low resistance Si substrate having the first principal surface and a second principal surface opposite thereto, a high resistance Si layer that is higher in resistivity than the low resistance Si substrate and a step of forming a nitride epitaxial layer on the high resistance Si layer.

With the present method, the nitride semiconductor device that uses the low resistance Si substrate as a semiconductor substrate and is a nitride semiconductor device that enables suppression of warping of the low resistance Si substrate and internal cracking of the nitride epitaxial layer and reduction of parasitic capacitance can be manufactured.

In the following, preferred embodiments of the present disclosure shall be described in detail with reference to the attached drawings.

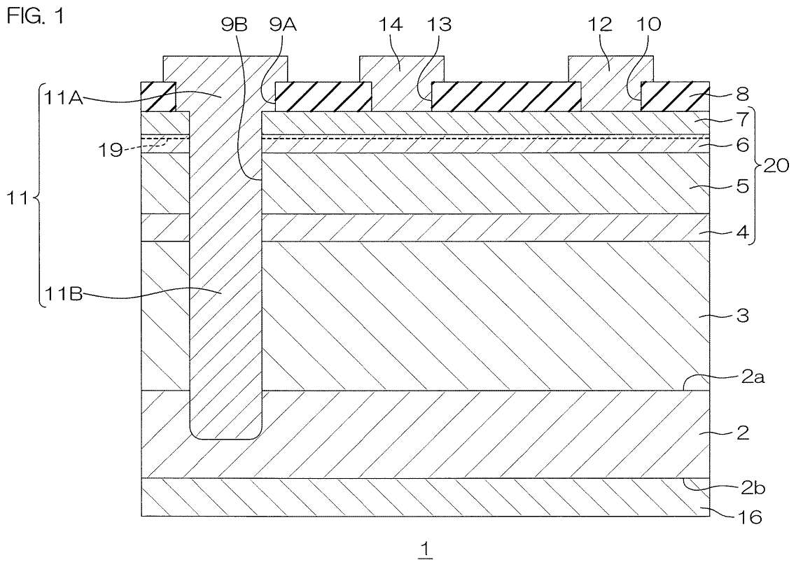

FIG. 1 is a sectional view for describing the arrangement of a nitride semiconductor device according to a first preferred embodiment of the present disclosure.

A nitride semiconductor device 1 includes a low resistance Si substrate (conductive Si substrate) 2 that has a first principal surface (front surface) 2a and a second principal surface (rear surface) 2b opposite thereto, a high resistance Si layer 3 that is formed on the first principal surface 2a of the low resistance Si substrate 2 and is higher in resistivity than the low resistance Si substrate 2, and a nitride epitaxial layer 20 that is disposed on the high resistance Si layer 3.

The nitride epitaxial layer 20 includes a buffer layer 4 that is formed on the high resistance Si layer 3, a semi-insulating nitride layer 5 that is formed on the buffer layer 4, a first nitride semiconductor layer 6 that is formed on the semi-insulating nitride layer 5, and a second nitride semiconductor layer 7 that is formed on the first nitride semiconductor layer 6.

Further, the nitride semiconductor device 1 includes an insulating film 8 that is formed on the second nitride semiconductor layer 7. Further, the nitride semiconductor device 1 includes a source electrode 11 that includes a main electrode portion 11A penetrating through a first source contact hole 9A formed in the insulating film 8 and being in ohmic contact with the second nitride semiconductor layer 7 and a drain electrode 12 that penetrates through a drain contact hole 10 formed in the insulating film 8 and is in ohmic contact with the second nitride semiconductor layer 7. The source electrode 11 and the drain electrode 12 are disposed at an interval.

Further, the nitride semiconductor device 1 includes a gate electrode 14 that penetrates through a gate contact hole 13 formed in the insulating film 8 and being in contact with the second nitride semiconductor layer 7. The gate electrode 14 is disposed between the source electrode 11 and the drain electrode 12. Further, the nitride semiconductor device 1 incudes a back electrode 16 that is formed on the second principal surface 2b of the low resistance Si substrate 2.

The low resistance Si substrate 2 is constituted of an Si substrate of low resistance. The first principal surface 2a of the low resistance Si substrate 2 is a (111) plane. An acceptor type impurity is contained in the low resistance Si substrate 2. The acceptor type impurity is, for example, boron and an impurity concentration is preferably not less than 1×10¹⁸ cm⁻³ and not more than 1×10²¹ cm⁻³. A resistivity of the low resistance Si substrate 2 is preferably not more than 0.01 Ω·cm. A thickness of the low resistance Si substrate 2 is, for example, approximately 50 μm to 700 μm. Here, if the low resistance Si substrate 2 is a 6-inch substrate, its thickness is, for example, approximately 600 μm to 700 μm.

The high resistance Si layer 3 is constituted of an Si layer that is higher in resistivity than the low resistance Si substrate 2. An acceptor type impurity is contained in the high resistance Si layer 3. The acceptor type impurity is, for example, boron and an impurity concentration is preferably not less than 1×10¹³ cm⁻³ and not more than 1×10¹⁶ cm⁻³. A resistivity of the high resistance Si layer 3 is preferably not less than 1 Ω·cm and more preferably not less than 1×10² Ω·cm. A thickness of the high resistance Si layer 3 is, for example, approximately 5 μm to 50 μm.

The buffer layer 4 is a buffering layer that is arranged to buffer strain resulting from mismatch of a lattice constant of the semi-insulating nitride layer 5 formed on the buffer layer 4 and a lattice constant of the high resistance Si layer 3. In this preferred embodiment, the buffer layer 4 is constituted of a multilayer buffer layer in which a plurality of nitride semiconductor films are laminated. In this preferred embodiment, the buffer layer 4 is constituted of a laminated film of an AlN film that is in contact with a front surface of the high resistance Si layer 3 and an AlGaN film that is laminated on a front surface (surface at an opposite side to the high resistance Si layer 3) of the AlN film. A thickness of the AlN film is approximately 0.2 μm and a thickness of the AlGaN film is approximately 0.1 μm to 1.0 μm. The buffer layer 4 may instead be constituted of a single film of an AlN film or a single film of AlGaN.

The semi-insulating nitride layer 5 is provided to suppress a leak current. In this preferred embodiment, the semi-insulating nitride layer 5 is constituted of a GaN layer that is doped with an impurity and a thickness thereof is approximately 1 μm to 10 μm. The impurity is, for example, C (carbon).

The first nitride semiconductor layer 6 constitutes an electron transit layer. The first nitride semiconductor layer 6 is constituted of an undoped GaN layer. A film thickness of the first nitride semiconductor layer 6 is, for example, approximately 0.05 μm to 1 μm. In this preferred embodiment, the film thickness of the first nitride semiconductor layer 6 is approximately 0.1 μm.

The second nitride layer 7 constitutes an electron supply layer. The second nitride semiconductor layer 7 is constituted of a nitride semiconductor of greater bandgap than the first nitride semiconductor layer 6. Specifically, the second nitride semiconductor layer 7 is constituted of a nitride semiconductor of higher Al composition than the first nitride semiconductor layer 6. In a nitride semiconductor, the higher the Al composition, the greater the bandgap. In this preferred embodiment, the second nitride semiconductor layer 7 is constituted of an Alₓ₁Ga₁₋ₓ₁N layer (0<x1≤1) and a thickness thereof is, for example, preferably approximately 1 nm to 100 nm and more preferably 5 nm to 50 nm. In this preferred embodiment, the thickness of the second nitride semiconductor layer 7 is approximately 20 nm and x1=0.2.

The first nitride semiconductor layer 6 (electron transit layer) and the second nitride semiconductor layer 7 (electron supply layer) are thus constituted of nitride semiconductors that differ in bandgap (Al composition) and a lattice mismatch occurs therebetween. Also, due to spontaneous polarizations of the first nitride semiconductor layer 6 and the second nitride semiconductor layer 7 and a piezo polarization due to the lattice mismatch between the two, an energy level of a conduction band of the first nitride semiconductor layer 6 at an interface between the first nitride semiconductor layer 6 and the second nitride semiconductor layer 7 is made lower than a Fermi level. Thereby, the inside first nitride semiconductor layer 6, a two-dimensional electron gas (2DEG) 19 spreads at a position close to the interface with the second nitride semiconductor layer 7 (for example, at a distance of approximately several Å from the interface).

The insulating film 8 is formed across substantially an entirety of a front surface of the second nitride semiconductor layer 7. In this preferred embodiment, the insulating film 8 is constituted of SiN. A thickness of the insulating film 8 is, for example, approximately 10 nm to 200 nm. In this preferred embodiment, the thickness of the insulating film 8 is approximately 100 nm. Besides SiN, the insulating film 8 may be constituted of SiO₂, SiN, SiON, Al₂O₃, AlN, AlON, HfO, HAN, HfON, HfSiON, AlON, etc.

In a laminated body of the low resistance Si substrate 2, the high resistance Si layer 3, and the nitride epitaxial layer 20 is formed a second source contact hole 9B that is in communication with the first source contact hole 9A and extends from a front surface of the nitride epitaxial layer 20 to a thickness intermediate portion of the low resistance Si substrate 2.

The source electrode 11 includes the main electrode portion 11A and an extension portion 11B. The main electrode portion 11A covers the first source contact hole 9A and a peripheral edge portion of the first source contact hole 9A at the insulating film 8 front surface. A portion of the main electrode portion 11A enters into the first source contact hole 9A. A peripheral edge portion of a lower surface of the portion of the main electrode portion 11A that enters inside the first source contact hole 9A is in contact with the front surface of the second nitride semiconductor layer 7 inside the first source contact hole 9A.

The extension portion 11B extends inside the second source contact hole 9B from a lower surface of the main electrode portion 11A. The extension portion 11B electrically connects the main electrode portion 11A to the low resistance Si substrate 2. The main electrode portion 11A is thereby electrically connected to the back electrode 16 via the extension portion 11B and the low resistance Si substrate 2.

The drain electrode 12 covers the drain contact hole 10 and a peripheral edge portion of the drain contact hole 10 at the insulating film 8 surface. A portion of the drain electrode 12 enters into the drain contact hole 10 and is in contact with the front surface of the second nitride semiconductor layer 7 inside the drain contact hole 10.

The source electrode 11 and the drain electrode 12 are constituted, for example, of a Ti/Al laminated film in which a Ti film and an Al film are laminated in that order from a lower layer. A thickness of the Ti film at the lower side is, for example, approximately 20 nm and a thickness of the Al film at an upper layer side is, for example, approximately 300 nm.

The source electrode 11 and the drain electrode 12 suffice to be constituted of a material with which ohmic contact can be established with respect to the second nitride semiconductor layer 7 (AlGaN layer). The source electrode 11 and the drain electrode 12 may be constituted of a Ti/Al/Ni/Au laminated film in which a Ti film, an Al film, an Ni film, and an Au film are laminated in that order from a lower layer.

The gate electrode 14 covers the gate contact hole 13 and a peripheral edge portion of the gate contact hole 13 at the insulating film 8 surface. A portion of the gate electrode 14 enters into the gate contact hole 13 and is in contact with the front surface of the second nitride semiconductor layer 7 inside the gate contact hole 13.

The gate electrode 14 is constituted, for example, of an Ni/Au laminated film in which an Ni film and an Au film are laminated in that order from a lower layer. A thickness of the Ni film at the lower layer side is, for example, approximately 10 nm and a thickness of the Au film at an upper layer side is, for example, approximately 600 nm. The gate electrode 14 suffices to be constituted of a material with which a Schottky barrier can be formed with respect to the second nitride semiconductor layer 7 (AlGaN layer).

The back electrode 16 is constituted, for example, of a material that contains gold (Au).

With the nitride semiconductor device 1, a heterojunction is formed by forming, on the first nitride semiconductor layer 6 (electron transit layer), the second nitride semiconductor layer 7 (electron supply layer) that differs in bandgap (Al composition). Thereby, the two-dimensional electron gas 19 is formed inside the first nitride semiconductor layer 6 near the interface of the first nitride semiconductor layer 6 and the second nitride semiconductor layer 7 and an HEMT that uses the two-dimensional electron gas 19 as a channel is formed.

In a state where a control voltage is not applied to the gate electrode 14, the source electrode 11 and the drain electrode 12 are connected to each other with the two-dimensional electron gas 19 as the channel. Therefore, the HEMT is of a normally-on type. When the control voltage such that a potential at the gate electrode 14 is made negative with respect to the source electrodes 11 is applied to the gate electrode 14, the two-dimensional electron gas 19 is interrupted and the HEMT is put in an off state.

With this preferred embodiment, since the high resistance Si layer 3 is formed on the low resistance Si substrate 2, a parasitic capacitance can be reduced in comparison to a case where the high resistance Si layer 3 is not formed on the low resistance Si substrate 2. When the low resistance Si substrate 2 is used, the film thickness of the nitride epitaxial layer 20 needs to be made large to reduce the parasitic capacitance. However, with this preferred embodiment, it is made possible to make the film thickness of the nitride epitaxial layer 20 small because the high resistance Si layer 3 is formed on the low resistance Si substrate 2. Suppression of warping of the low resistance Si substrate 2 and internal cracks in the nitride epitaxial layer 20 and reduction of parasitic capacitance are thereby enabled.

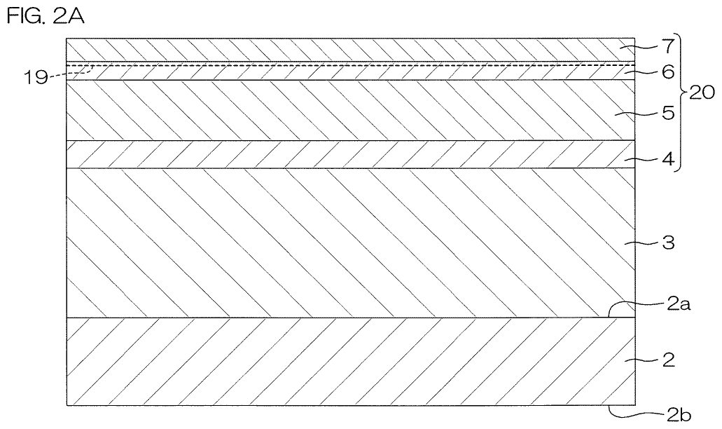

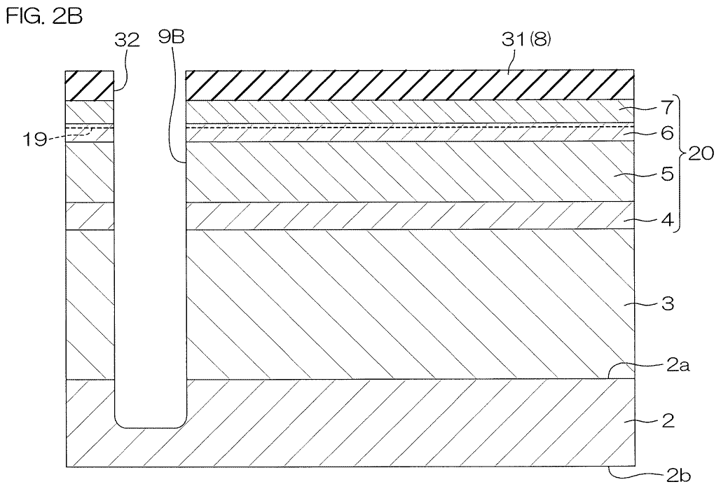

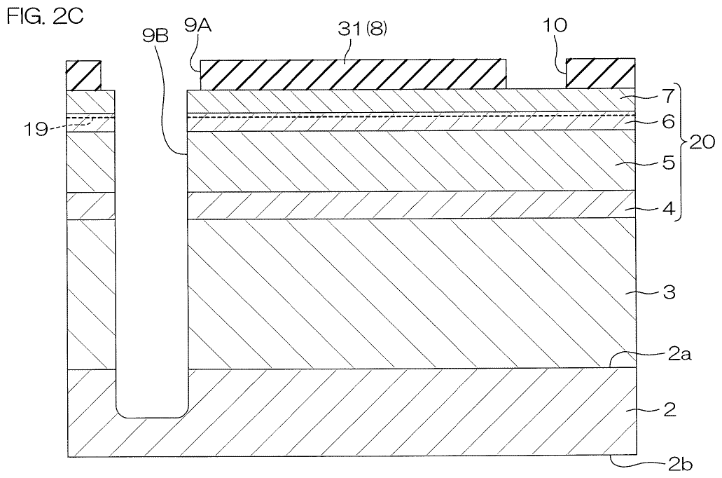

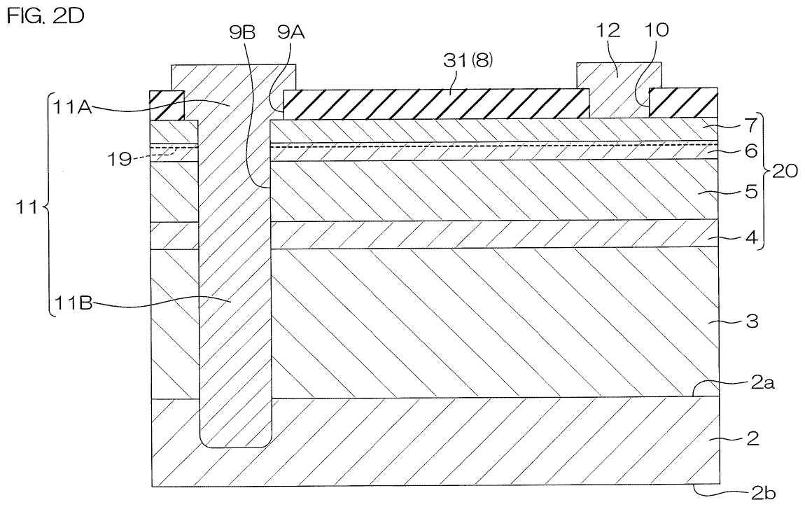

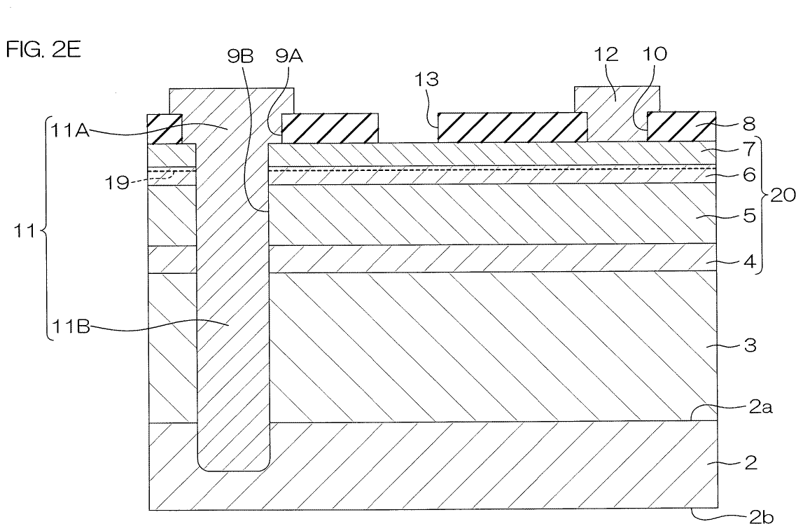

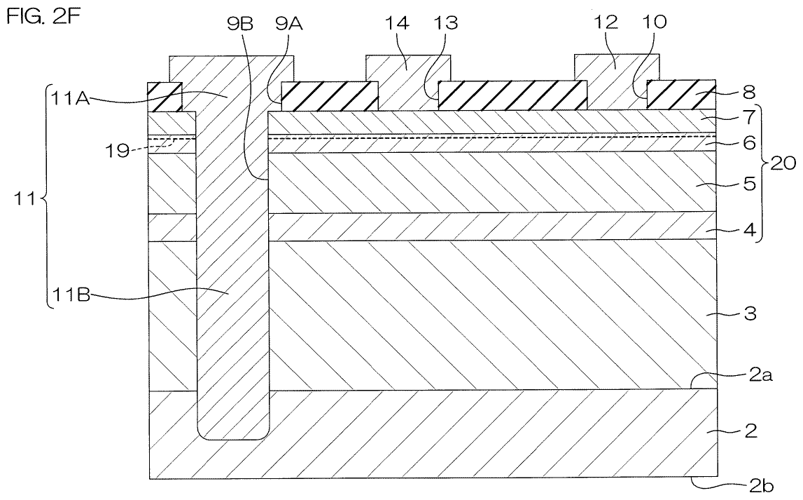

FIG. 2A to FIG. 2F are sectional views for describing an example of a manufacturing process of the nitride semiconductor device 1 described above and show a sectional structure in a plurality of phases in the manufacturing process.

First, as shown in FIG. 2A, the high resistance Si layer 3 is formed on the first principal surface 2a of the low resistance Si substrate 2, for example, by a CVD (chemical vapor deposition) method. Also, the buffer layer 4, the semi-insulating nitride layer 5, the first nitride semiconductor layer (electron transit layer) 6, and the second nitride semiconductor layer (electron supply layer) 7 are epitaxially grown in that order on the high resistance Si layer 3 by the CVD method. The nitride epitaxial layer 20 constituted of the buffer layer 4, the semi-insulating nitride layer 5, the first nitride semiconductor layer 6, and the second nitride semiconductor layer 7 is thereby formed on the high resistance Si layer 3.

Next, as shown in FIG. 2B, an insulating material film 31 that is a material film of the insulating film 8 is formed on the second nitride semiconductor layer 7 by a plasma CVD method, LPCVD (low pressure CVD) method, MOCVD method, sputtering method, etc. A resist film (not shown) is then formed on the insulating material film 31 in a region excluding a region in which the second source contact hole 9B is to be formed. By dry-etching the insulating material film 31 via the resist film, the second source contact hole 9B and a portion 32 of the first source contact hole 9A are formed. The resist film is thereafter removed. Here, the second source contact hole 9B and the portion 32 of the first source contact hole 9A may be formed by laser processing instead.

Next, as shown in FIG. 2C, a resist film (not shown) is formed on the insulating material film 31 in a region excluding regions in which the first source contact hole 9A and the drain contact hole 10 are to be formed. By dry-etching the insulating material film 31 via the resist film, the first source contact hole 9A that is in communication with the second source contact hole 9B and the drain contact hole 10 are formed. The first source contact hole 9A penetrates through the insulating material film 31, a peripheral edge portion of a lower surface thereof reaches the second nitride semiconductor layer 7, and a portion surrounded by the peripheral edge portion of the lower surface is connected to the second source contact hole 9B. The drain contact hole 10 penetrates through the insulating material film 31 and reaches the second nitride semiconductor layer 7.

Next, as shown in FIG. 2D, an electrode film that is a material film of the source electrode 11 and the drain electrode 12 is formed on the second nitride semiconductor layer 7, for example, by an electron beam vapor deposition method, sputtering method, etc., such as to cover the insulating material film 31. The electrode film is constituted, for example, of a Ti/Al laminated film in which a Ti film and an Al film are laminated in that order from a lower layer.

Next, a resist film that covers a source electrode preparation planned region and a drain electrode preparation planned region on the electrode film front surface is formed. By then selectively etching the electrode film using the resist film as a mask, the source electrode 11 including the main electrode portion 11A and the extension portion 11B and the drain electrode 12 are obtained. Thereafter, the resist film is removed.

Next, as shown in FIG. 2E, a resist film (not shown) is formed on the insulating material film 31, the source electrode 11, and the drain electrode 12 in a region excluding a region in which the gate contact hole 13 is to be formed. By dry-etching the insulating material film 31 via the resist film, the gate contact hole 13 is formed in the insulating material film 31. Thereby, the insulating material film 31 is patterned and the insulating film 8 is obtained. Thereafter, the resist film is removed.

Next, as shown in FIG. 2F, an electrode film that is a material film of the gate electrode 14 is formed on the second nitride semiconductor layer 7, for example, by an electron beam vapor deposition method, sputtering method, etc., such as to cover the insulating material film 31. The electrode film is constituted, for example, of an Ni/Au laminated film in which an Ni film and an Au film are laminated in that order from a lower layer. Next, a resist film that covers a gate electrode preparation planned region on the electrode film front surface is formed. By then selectively etching the electrode film using the resist film as a mask, the gate electrode 14 is formed. Here, the gate electrode 14 may be formed by a lift-off method instead.

Lastly, by forming the back electrode 16 on the second principal surface 2b of the low resistance Si substrate 2, the nitride semiconductor device 1 such as shown in FIG. 1 is obtained.

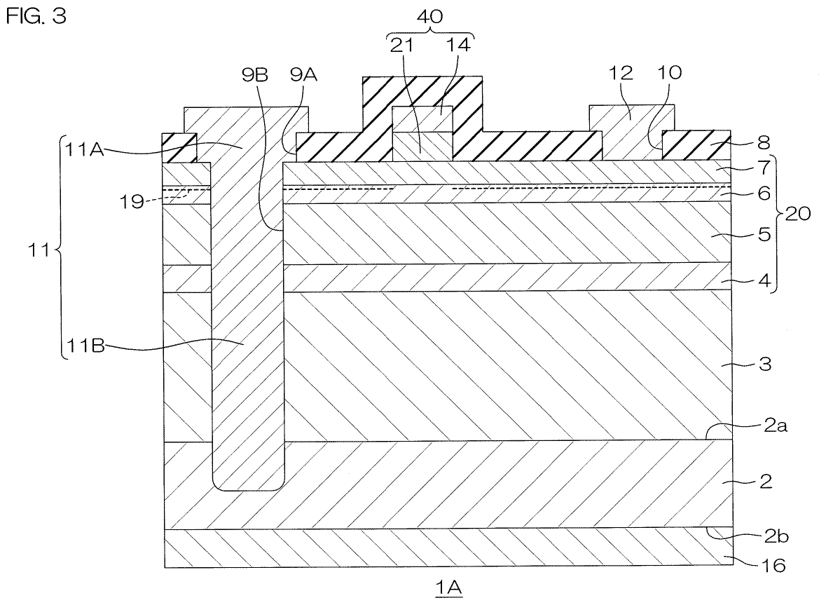

FIG. 3 is a sectional view for describing the arrangement of a nitride semiconductor device according to a second preferred embodiment of the present disclosure. In FIG. 3, respective portions corresponding to those in FIG. 1 described above are indicated with the same reference signs attached as in FIG. 1.

A nitride semiconductor device 1A of FIG. 3 differs from the nitride semiconductor device 1 of FIG. 1 in a point that a nitride semiconductor gate layer 21 is provided between the gate electrode 14 and the second nitride semiconductor layer 7.

With the nitride semiconductor device 1A of FIG. 3, a gate portion 40 is arranged from the nitride semiconductor gate layer 21 and the gate electrode 14 formed thereon. The insulating film 8 covers the gate portion 40.

The nitride semiconductor gate layer 21 is constituted of a nitride semiconductor doped with an acceptor type impurity. In this preferred embodiment, the nitride semiconductor gate layer 21 is constituted of a GaN layer (p type GaN layer) doped with the acceptor type impurity and a thickness thereof is approximately 60 nm to 130 nm. A concentration of the acceptor type impurity is preferably not less than 3×10¹⁷ cm⁻³. The acceptor type impurity is magnesium (Mg). The acceptor type impurity may be an acceptor type impurity other than magnesium such as zinc (Zn), carbon (C), etc., instead.

The nitride semiconductor gate layer 21 is provided to change a conduction band of an interface formed by the first nitride semiconductor layer 6 (electron transit layer) and the second nitride semiconductor layer 7 (electron supply layer) in a region directly below the gate portion 40 such that the two-dimensional electron gas 19 is not generated in the region directly below the gate portion 40 in the state in which the gate voltage is not applied.

Below the gate electrode 14, energy levels of the first nitride semiconductor layer 6 and the second nitride semiconductor layer 7 are raised by the acceptor contained in the nitride semiconductor gate layer 21. The energy level of the conduction band at the heterojunction interface between the first nitride semiconductor layer 6 and the second nitride semiconductor layer 7 is thus made higher than the Fermi level. The two-dimensional electron gas 19 due to the spontaneous polarizations of the first nitride semiconductor layer 6 and the second nitride semiconductor layer 7 and the piezo polarization due to the lattice mismatch between the two is thus not formed directly below the gate electrode 14 (gate portion 40).

Thus, when a bias is not applied to the gate electrode 14 (in a zero bias state), the channel due to the two-dimensional electron gas 19 is interrupted directly below the gate electrode 14. A normally-off HEMT is thereby realized. When an appropriate ON voltage (for example, 5 V) is applied to the gate electrode 14, a channel is induced inside the first nitride semiconductor layer 6 directly below the gate electrode 14 and the two-dimensional electron gas 19 at both sides of the gate electrode 14 become connected. Source-drain conduction is thereby achieved.

A method for manufacturing the nitride semiconductor device 1A of FIG. 3 differs in the following points in comparison to the method for manufacturing the nitride semiconductor device 1 of FIG. 1.

In the step of FIG. 2A described above, a gate layer material film that is a material film of the nitride semiconductor gate layer 21 is formed on the second nitride semiconductor layer 7. Thereafter, a gate electrode film that is a material film of the gate electrode 14 is formed on the gate layer material film. By then patterning the gate electrode film and the gate layer material film, the gate portion 40 constituted of the second nitride semiconductor layer 7 and the gate electrode 14 formed thereon is obtained. By thereafter performing the same steps as the steps of FIG. 2B onward excluding those of FIG. 2E and FIG. 2F described above, the nitride semiconductor device 1A such as shown in FIG. 3 is obtained.

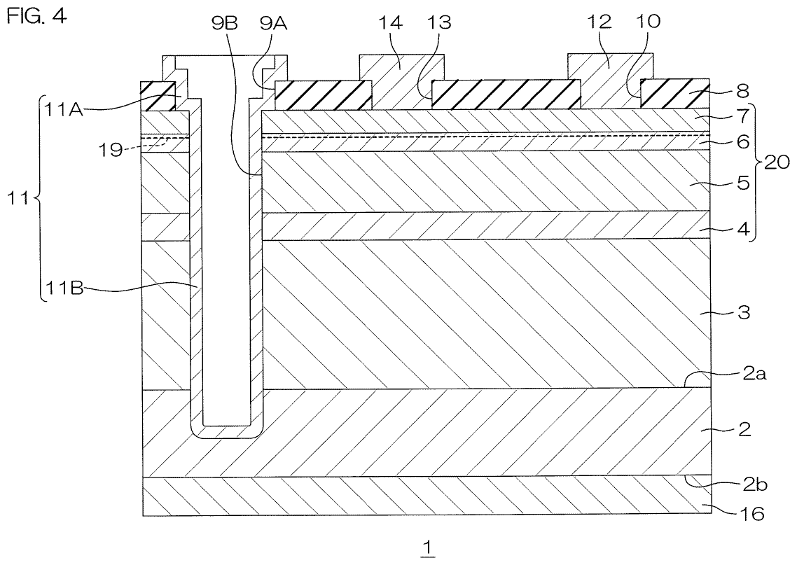

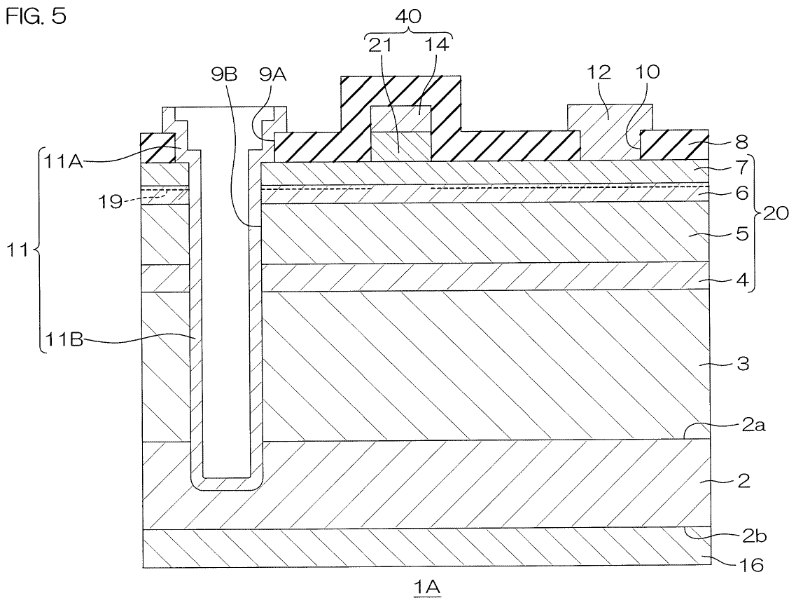

FIG. 4 is a sectional view showing a modification example of the source electrode 11 of the nitride semiconductor device 1 of FIG. 1. In FIG. 4, respective portions corresponding to those in FIG. 1 described above are indicated with the same reference signs attached as in FIG. 1. FIG. 5 is a sectional view showing a modification example of the source electrode 11 of the nitride semiconductor device 1A of FIG. 3. In FIG. 5, respective portions corresponding to those in FIG. 3 described above are indicated with the same reference signs attached as in FIG. 3.

With the first or second preferred embodiment described above, inside the first source contact hole 9A and the second source contact hole 9B, the source electrode 11 is formed such as to completely fill the spaces inside the holes 9A and 9B. However, as shown in FIG. 4 and FIG. 5, the source electrode 11 does not have to completely fill the spaces inside the holes 9A and 9B. Specifically, inside the holes 9A and 9B, the source electrode 11 may be formed as a thin film on inner surfaces of the holes 9A and 9B.

The second source contact hole 9B may penetrate through the low resistance Si substrate 2. In this case, the main electrode portion 11A is electrically connected to the back electrode 16 via the extension portion 11B that is embedded inside the second source contact hole 9B.

Also, although with the first and second preferred embodiments described above, the semi-insulating nitride layer 5 is formed on the buffer layer 4, the semi-insulating nitride layer 5 does not have to be formed.

Also, although with the first and second preferred embodiments described above, an example where the first nitride semiconductor layer (electron transit layer) 6 is constituted of a GaN layer and the second nitride semiconductor layer (electron supply layer) 7 is constituted of an AlGaN layer was described, the first nitride semiconductor layer 6 and the second nitride semiconductor layer 7 suffice to differ in bandgap (for example, in Al composition) and other combinations are also possible. For example, as combinations of the first nitride semiconductor layer 6/second nitride semiconductor layer 7, GaN/AlN, AlGaN/AlN, etc., can be cited as examples.

While preferred embodiments of the present disclosure were described in detail above, these are merely specific examples used to clarify the technical contents of the present disclosure and the present disclosure should not be interpreted as being limited to these specific examples and the scope of the present disclosure is limited only by the appended claims.

What is claimed is:

1. A nitride semiconductor device comprising:
a low resistance Si substrate that has a first principal surface and a second principal surface opposite thereto;
a high resistance Si layer that is formed on the first principal surface and is higher in resistivity than the low resistance Si; and
a nitride epitaxial layer that is disposed on the high resistance Si layer.

2. The semiconductor device according to claim 1, wherein the first principal surface is a (111) plane.

3. The semiconductor device according to claim 1, wherein a resistivity of the low resistance Si substrate is not more than 0.01 Ω·cm and
a resistivity of the high resistance Si layer is not less than 1 Ω·cm.

4. The semiconductor device according to claim 1, wherein an acceptor type impurity is contained in each of the low resistance Si substrate and the high resistance Si layer,
an acceptor type impurity concentration of the low resistance Si substrate is not less than 1×10¹⁸ cm⁻³ and not more than 1×10²¹ cm⁻³, and
an acceptor type impurity concentration of the high resistance Si layer is not less than 1×10¹³ cm⁻³ and not more than 1×10¹⁶ cm⁻³.

5. The semiconductor device according to claim 4, wherein the acceptor type impurity is boron.

6. The semiconductor device according to claim 1, wherein the nitride epitaxial layer includes
a buffer layer that is formed on the high resistance Si layer and is constituted of a nitride semiconductor,
a first nitride semiconductor layer that is disposed on the buffer layer and constitutes an electron transit layer, and
a second nitride semiconductor layer that is formed on the first nitride semiconductor layer, constitutes an electron supply layer, and is higher in bandgap than the first nitride semiconductor layer.

7. The semiconductor device according to claim 6, wherein the buffer layer includes an AlN layer that is formed on the high resistance Si layer and an AlGaN layer that is formed on the AlN layer,
the first nitride semiconductor layer includes an undoped GaN layer that is disposed on the buffer layer, and
the second nitride semiconductor layer includes an AlGaN layer.

8. The semiconductor device according to claim 6, comprising: a semi-insulating nitride layer that is disposed between the buffer layer and the first nitride semiconductor layer.

9. The semiconductor device according to claim 8, wherein the buffer layer includes an AlN layer that is formed on the high resistance Si layer and an AlGaN layer that is formed on the AlN layer,
the semi-insulating nitride layer includes a semi-insulating GaN layer that is disposed on the buffer layer and is doped with an impurity,
the first nitride semiconductor layer includes an undoped GaN layer that is formed on the semi-insulating nitride layer, and
the second nitride semiconductor layer includes an AlGaN layer.

10. The semiconductor device according to claim 9, wherein the impurity is carbon.

11. The semiconductor device according to claim 1, comprising: a source electrode, a drain electrode, and a gate electrode that are disposed on the nitride epitaxial layer; and
wherein a hole reaching the low resistance Si substrate from a front surface of the nitride epitaxial layer is formed, and
the source electrode is electrically connected to the low resistance Si substrate via the hole.

12. The semiconductor device according to claim 11, comprising: a nitride semiconductor gate layer that is formed between the gate electrode and the nitride epitaxial layer and is constituted of a nitride semiconductor layer containing an acceptor type impurity.

13. The semiconductor device according to claim 11, comprising: a rear surface electrode that is formed on the second principal surface.

14. A method for manufacturing a nitride semiconductor device comprising:
a step of forming, on a first principal surface of a low resistance Si substrate having the first principal surface and a second principal surface opposite thereto, a high resistance Si layer that is higher in resistivity than the low resistance Si substrate; and
a step of forming a nitride epitaxial layer on the high resistance Si layer.
